(19) United States
(12) Patent Application Publication
(10) Pub. No.: US 2008/0017405 A1
(43) Pub. Date: Jan. 24, 2008

(54) Circuit board and anti-static module thereof

(75) Inventors: Chien-Hsiang Huang, Taipei Hsien (TW); Yin-Jui Chuang, Taipei Hsien (TW); Muh-Jin Uang, Taipei Hsien (TW)

Correspondence Address: BIRCH STEWART KOLASCH & BIRCH, PO BOX 747, FALLS CHURCH, VA, 22040-0747, US

(73) Assignee: GIGA-BYTE TECHNOLOGY CO., LTD.

(21) Appl. No.: 11/489,599

(22) Filed: Jul. 20, 2006

(51) Int. Cl. H05K 1/16

(52) U.S. Cl. 174/260; 361/760

(57) ABSTRACT

An anti-static module for a circuit board having a plurality of grounding traces comprises a copper region having a tip toward one of the grounding traces. Static electricity on the circuit board can be removed by discharging from the tip to the grounding trace, avoiding damage to the elements on the circuit board.

### BACKGROUND OF THE INVENTION

1. Field of the Invention

The invention relates to an anti-static module, and in particular relates to an anti-static module directing static electricity by point discharge.

2. Description of the Related Art

Static electricity may enter a circuit board from the exterior environment, for example by contacting with an interface of the circuit board. The static electricity accumulating on the circuit board can damage electronic elements thereon, for example, an IC chip can accept voltage of static electricity less than 2 kV. An anti-static element prevents the static electricity from accumulating on the circuit board.

A typical anti-static element is a Zener diode. Referring to FIG. 1, a pad 40 for the Zener diode is formed on the circuit board. The region “A” in FIG. 1 is an area for the Zener diode (not shown), through which four signal traces (the numeral 10) pass. Numeral 20 is a grounding trace, numeral 30 is a power trace and numeral 40 is pad for the Zener diode. The static electricity of the circuit board is directed to the grounding trace 30 to reduce the static electricity accumulating on the circuit board below the voltage limit of electronic elements. As the size of the circuit board is reduced, it is desired to use fewer electronic elements.

### BRIEF SUMMARY OF INVENTION

The invention provides an anti-static module in a circuit board without adding any external anti-static element. The anti-static module also cooperates with the Zener diode to enhance anti-static capability.

An embodiment of an anti-static module of the invention comprises a copper region formed on a circuit board. The copper region comprises at least one tip toward one of the grounding traces on the circuit board, with an anti-static element is selectively disposed on the copper region.

The tip is separated from the grounding trace by an appropriate distance, greater than or equal to the minimal distance between two traces formed during manufacture.

When the anti-static element is disposed on the copper region, it connects the copper region and the grounding trace. The anti-static element can be a Zener diode. The copper region serves as a pad on which the anti-static element is disposed, whereby the anti-static element is connected to the circuit board.

A detailed description is given in the following embodiments with reference to the accompanying drawings.

### BRIEF DESCRIPTION OF DRAWINGS

The patent or application file contains at least one drawing executed in color. Copies of this patent or patent application publication with color drawing(s) will be provided by the office upon request and payment of the necessary fee.

The invention can be more fully understood by reading the subsequent detailed description and examples with references made to the accompanying drawings, wherein:

FIG. 1 is a layout diagram of a conventional circuit board; and

FIG. 2 is a schematic view of a circuit board with anti-static module of the invention.

### DETAILED DESCRIPTION OF INVENTION

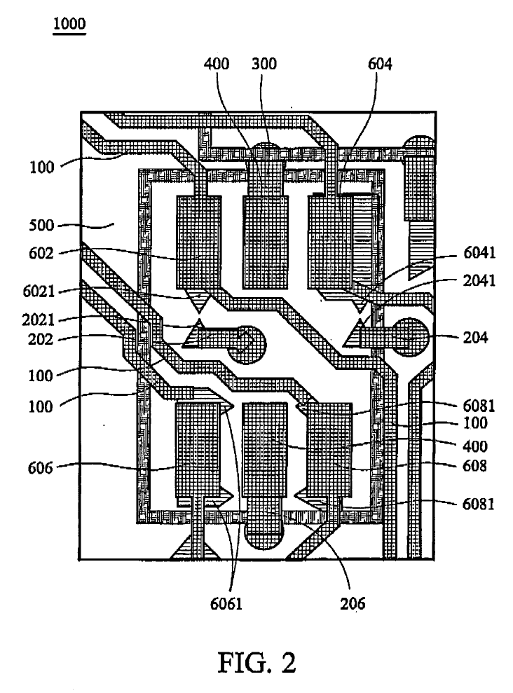

Referring to FIG. 2, a circuit board 1000 of the invention comprises a main body 500, a plurality of signal traces 100, a plurality of grounding traces 202, 204 and 206, a power trace 300, and a plurality of copper regions 602, 604, 606 and 608 formed on the main body 500. The signal traces 100 are connected to the copper regions 602, 604. 606 and 608 respectively. The power trace 300 is disposed between the upper copper regions 602 and 604, and the grounding trace 206 is disposed between the lower copper regions 606 and 608. Two grounding traces 202 and 204 are disposed between the upper copper regions and the lower copper regions.

A triangular tip 6021 formed on the copper region 602 extends toward the grounding trace 202. In this embodiment, a tip 2021 formed on the grounding trace 202 corresponds to the tip 6021, which shortens the distance between the tip 6021 and the grounding trace 202. Similarly, a tip 6041 formed on the copper region 604 extends toward the grounding trace 204. A tip 2041 formed on the grounding trace 204 corresponds to the tip 6041.

Further, the grounding trace can have no tips, for example grounding trace 206. The copper regions 606 and 608 have two tips 6061 and 6081, respectively, toward the grounding trace 206. As the tips 6061 and 6081 are close to the grounding trace 206, no tips are needed on the grounding trace 206.

The tips on the copper region have potential difference from the grounding trace, whereby static electricity discharges from the tips to the grounding trace. The static electricity transmitted from exterior environment via the signal trace 100 to the circuit board 1000 discharges to the grounding traces 202, 204 and 206. The amount, shape and positions of the tip are not limited, according to circuit design and layout. The distance between the tip to the grounding trace is as small as possible, but limited by the minimal distance between two traces formed during manufacture. Too small a distance may cause trace short. For the current technology, the minimal distance is 5 mil.

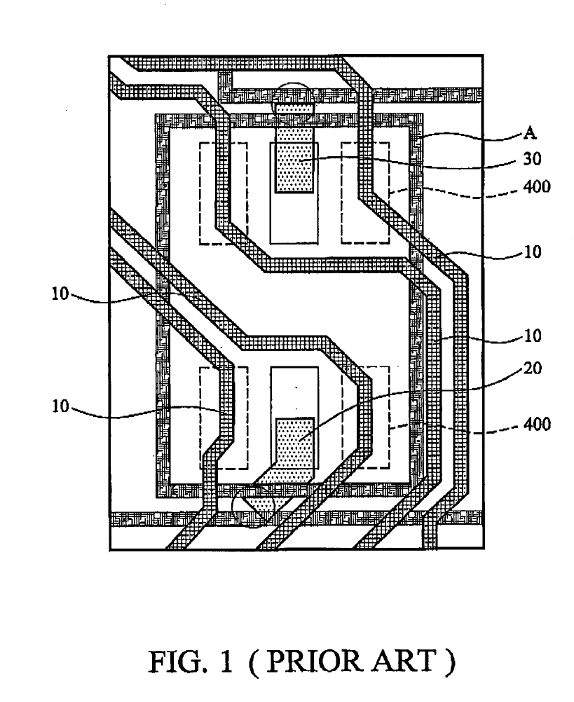

The invention is applied to a main board (CAYMAN-RH) produced by GIGA-BYTE technology Co., LTD. Static electricity test is performed on the USB interface. For the circuit layout of FIG. 1, the voltage limit of the main board is 3.2 kV. For the circuit layout of FIG. 2, the voltage limit of the main board reaches 4 kV.

In addition, for some circuit boards with high voltage limits, the Zener diode can be combined with the tips. In such a condition, the copper regions 602, 604, 606 and 608 and pads 400 can be served as pads for the Zener diode electrically connecting to the circuit board 1000. Two pads 400 are connected to the power trace 300 and the grounding trace 206. The combination of Zener diode and the tips raises the voltage limit to 9 kV.

The tip can be formed on the pads for the Zener diode in certain circuit boards, thereby raising the voltage limit of the circuit board. The invention provides flexibility in anti-static design. Tips are added to the original circuit layout, which can reach the same voltage limit as the Zener diode used in conventional technology. The combination of the tips and the Zener diode can reach even higher voltage limit.

In addition to the Zener diode, the invention can also be applied to the pads for anti-static element of Video chips or other I/O traces needed protection from static electricity.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An anti-static module for a circuit board having a plurality of grounding traces, comprising a copper region formed on the circuit board and comprising at least one tip toward one of the grounding traces, wherein an anti-static element is selectively disposed on the copper region.

2. The anti-static module as claimed in claim 1, wherein the tip is separated from the grounding trace by an appropriate distance.

3. The anti-static module as claimed in claim 2, wherein the minimum of the appropriate distance exceeds or is equal to the minimal distance between two traces formed during manufacture.

4. The anti-static module as claimed in claim 1, wherein when the anti-static element is disposed on the copper region, the anti-static element connects the copper region and the grounding trace.

5. The anti-static module as claimed in claim 4, wherein the anti-static element is a Zener diode.

6. The anti-static module as claimed in claim 4, wherein the copper region serves as a pad on which the anti-static element is disposed, whereby the anti-static element is connected to the circuit board.

7. A circuit board, comprising:
a main body;
a plurality of grounding traces; and
a copper region formed on the main body and comprising at least one tip toward one of the grounding traces, wherein an anti-static element is selectively disposed on the copper region.

8. The circuit board as claimed in claim 7, wherein the tip is separated from the grounding trace by an appropriate distance.

9. The circuit board as claimed in claim 8, wherein the minimum of the appropriate distance exceeds or is equal to the minimal distance between two traces formed by a process manufacturing the circuit board.

10. The circuit board as claimed in claim 7, wherein when the anti-static element is disposed on the copper region, the anti-static element connects the copper region and the grounding trace.

11. The circuit board as claimed in claim 10, wherein the copper region serves as a pad on which the anti-static element is disposed, whereby the anti-static element is connected to the circuit board.

12. The circuit board as claimed in claim 10, wherein the anti-static element is a Zener diode.
